(19) United States
(12) Patent Application Publication
(10) Pub. No.: US 2008/0268589 A1
(43) Pub. Date: Oct. 30, 2008

(54) SHALLOW TRENCH DIVOT CONTROL POST

(75) Inventors: David Gerald Farber, Wylie, TX (US); Toan Tran, Rowlett, TX (US); Craig Henry Huffman, Krugerville, TX (US); Brian K. Kirkpatrick, Allen, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/742,254

(22) Filed: Apr. 30, 2007

(51) Int. Cl. H01L 21/8238; H01L 29/76

(52) U.S. Cl. 438/218; 257/369; 257/E29.226; 257/E21.632

(57) ABSTRACT

The disclosure provides a method of manufacturing a semiconductor device. The method comprises forming a shallow trench isolation structure, including performing a wet etch process to remove a patterned pad oxide layer located on a semiconductor substrate. The wet etch thereby produces a divot on upper lateral edges of a insulator-filled trench in the semiconductor substrate. Forming the shallow trench isolation structure also includes forming a nitride post on a vertical wall of the divot. Forming the nitride post includes depositing a nitride layer on the insulator, and dry etching the nitride layer. The dry etch is selective towards the nitride located adjacent the vertical wall such that a portion of the nitride layer remains on the vertical wall subsequent to the dry etching.

### TECHNICAL FIELD

The disclosure is directed, in general, to semiconductor devices and more specifically to a semiconductor device comprising a shallow trench isolation (STI) structure and its method of manufacture.

### BACKGROUND

In the fabrication of semiconductor devices, STI structures can be formed between active areas which are configured to have active devices (e.g., transistors, memory cells). Typically, the STI structures are formed early in the semiconductor device's fabrication process, e.g., before forming the active devices. Conventional STI structure fabrication involves forming shallow openings or trenches in predefined isolation regions of a semiconductor substrate. The shallow trenches are then filled with insulating material to provide electrical isolation between active devices subsequently formed in the active regions of the substrate.

Conventional STI structure fabrication processes can cause the formation of unwanted openings or “divots” in the insulating material at the upper corners of the shallow trench.

The divots can cause a number of different problems during the later fabrication, or function, of active devices. E.g., the divot can create depth of focus issues that interfere with the accurate photolithographic patterning of active device features (e.g., a transistor gate). It can be problematic to metalize device features (e.g., source and drain regions) that are located in the vicinity of divots without creating electrical shorts within the active devices. Some materials deposited to form an active device feature can inadvertently get deposited into a divot, thereby causing the device to have undesirable electrical properties. E.g., polysilicon deposited as part of forming a transistor gate can get deposited into a divot, thereby causing a non-uniform electrical field to be generated in the channel region of the transistor.

Accordingly, what is needed is a method for manufacturing semiconductor devices having STI structures that addresses the drawbacks of the prior art methods and devices.

### SUMMARY

The disclosure provides a method of manufacturing a semiconductor device. The method comprises forming a STI structure, including performing a wet etch process to remove a patterned pad oxide layer located on a semiconductor substrate. The wet etch thereby produces a divot on upper lateral edges of a insulator-filled trench in the semiconductor substrate. Forming the STI structure also includes forming a nitride post on a vertical wall of the divot. Forming the nitride post includes depositing a nitride layer on the insulator, and dry etching the nitride layer. The dry etch is selective towards the nitride located adjacent the vertical wall such that a portion of the nitride layer remains on the vertical wall subsequent to the dry etching.

In another embodiment of manufacturing the device, forming a STI structure includes depositing a pad oxide layer and a nitride layer on a semiconductor substrate. The nitride layer, the pad oxide layer, and the substrate are patterned to form a trench opening in the substrate. The trench opening is filled with an insulator. The pad oxide layer is removed using a wet etch process that produces a divot on upper lateral edges of the insulator. A nitride post is formed on a vertical wall of the divot as described above. A gate oxide layer is formed on the substrate, the gate oxide being adjacent to the nitride post. Portions of the gate oxide layer are masked and unmasked portions of the gate oxide layer are removed using a second wet etch process.

Another embodiment is a semiconductor device comprising the STI structure and a transistor adjacent to the STI structure. The STI structure includes a silicon oxide insulator filling a trench in a semiconductor substrate. Upper edges of the silicon oxide insulator each have a divot. The divot has at least one vertical wall. The STI structure also includes a silicon nitride post on the vertical wall. A height of the silicon nitride post is substantially equal to a step height of the divot.

### BRIEF DESCRIPTION OF DRAWINGS

The disclosure is described with reference to example embodiments and to accompanying drawings, wherein:

FIGS. 1 to 8 illustrate cross-section views of selected steps in an example method of manufacturing a semiconductor device having the STI structure of the disclosure.

### DETAILED DESCRIPTION

The present disclosure benefits from the discovery that forming nitride posts on the vertical wall of a divot can substantially prevent the expansion in the size of the divot during subsequent semiconductor device fabrication steps. By forming the nitride posts early on in the device's manufacturing process, e.g., during STI fabrication, the subsequently formed active devices do not encounter the same degree of divot-related problems as conventionally formed devices.

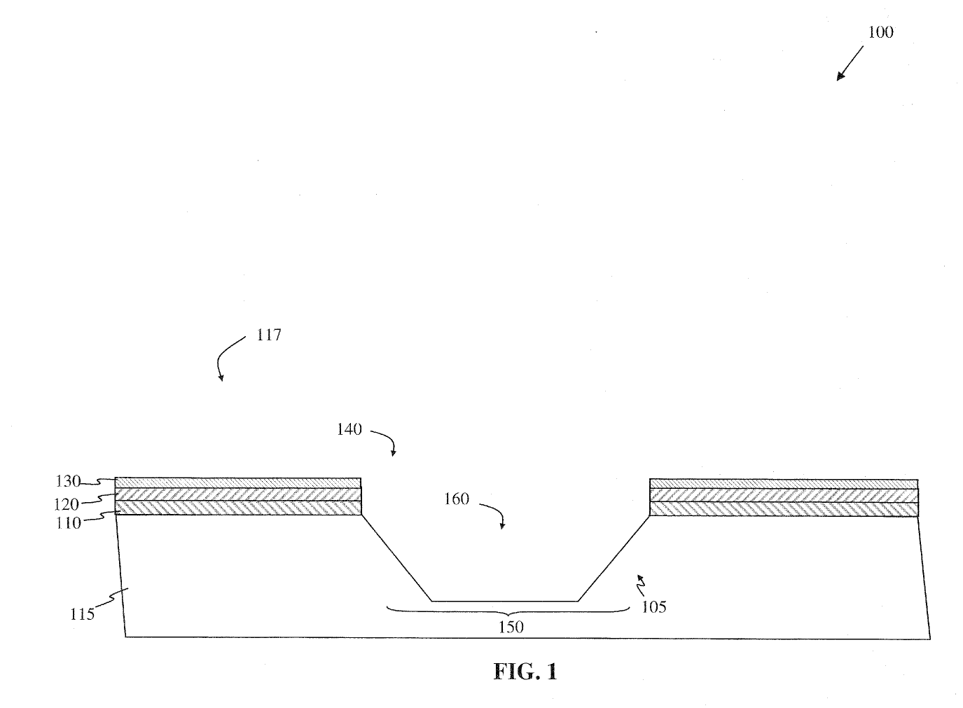

FIGS. 1 to 8 illustrate cross-section views of selected steps in an example method of manufacturing a semiconductor device 100 that includes forming a STI structure 105 of the disclosure. FIG. 1 shows the device 100 after forming a pad oxide layer 110 on a semiconductor substrate 115 (e.g., on surface 117), and a nitride layer 120 on the pad oxide layer 110. E.g., the pad oxide layer 110 (e.g., silicon oxide) can be formed on a silicon wafer substrate 115 using thermal oxidation growth, chemical vapor deposition (CVD), or other conventional processes. The nitride layer 120 (e.g., silicon nitride) can be similarly formed using conventional processes (e.g., CVD). The pad oxide layer 110 and nitride layer 120 serve as sacrificial structures to protect the underlying substrate 115 during subsequent processing steps, and are later removed. FIG. 1 also shows the device 100 after forming a patterned resist layer 130 on the pad oxide layer 110 and nitride layer 120. E.g., a conventional photoresist material 130 can be deposited on the nitride layer 120 and then patterned to form a patterned opening 140 over a predefined isolation region 150 of the substrate 115.

FIG. 1 also shows the device 100 after patterning the nitride layer 120, the pad oxide layer 110, and the substrate 115 to form a trench opening 160 in the substrate 115. E.g., an etching process, such as reactive ion etching (RIE), can be used to remove portions of the nitride layer 120, the pad oxide layer 110 and portions of the substrate 115 lying below the pattern opening 140.

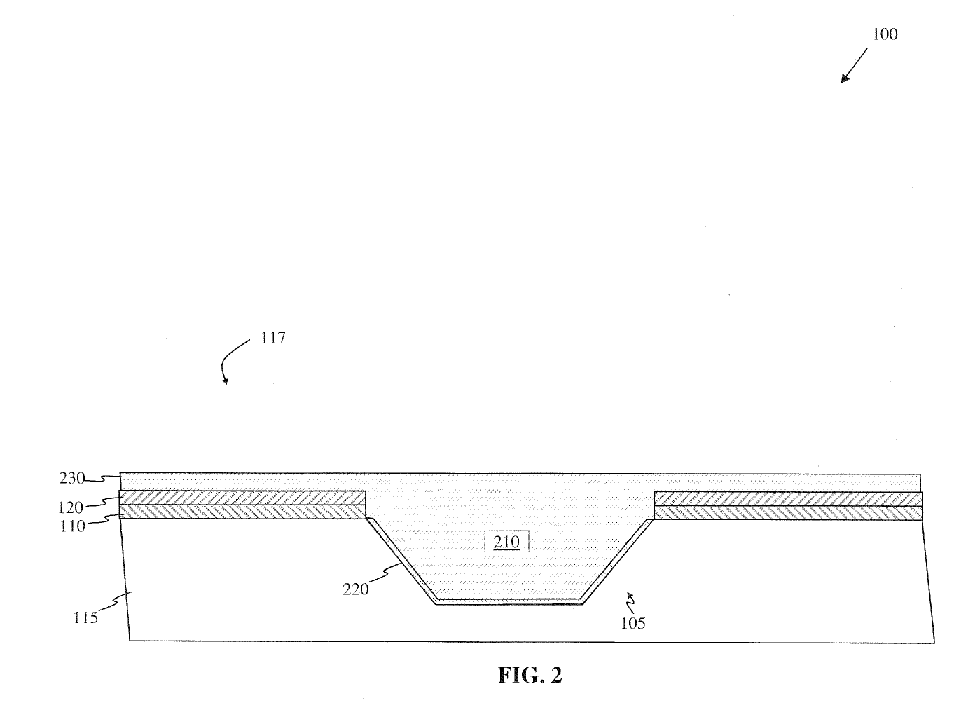

FIG. 2 shows the device 100 after removing the patterned resist layer 130 (FIG. 1), e.g., using an organic solvent wash. FIG. 2 also shows the device after filling the trench opening 140 with an insulator 210. E.g., an insulating liner layer 220 of silicon oxide can be grown on the exposed portions of the substrate 115 in the trench opening 140, using a conventional thermal oxide growth process. Then a bulk insulating layer 230 of silicon oxide can be deposited, e.g., by plasma enhanced CVD of tetraethylorthosilicate (TEOS) on the liner layer 220. As illustrated in FIG. 2, the bulk insulating layer 230 can cover the substrate 115, including the nitride layer 120.

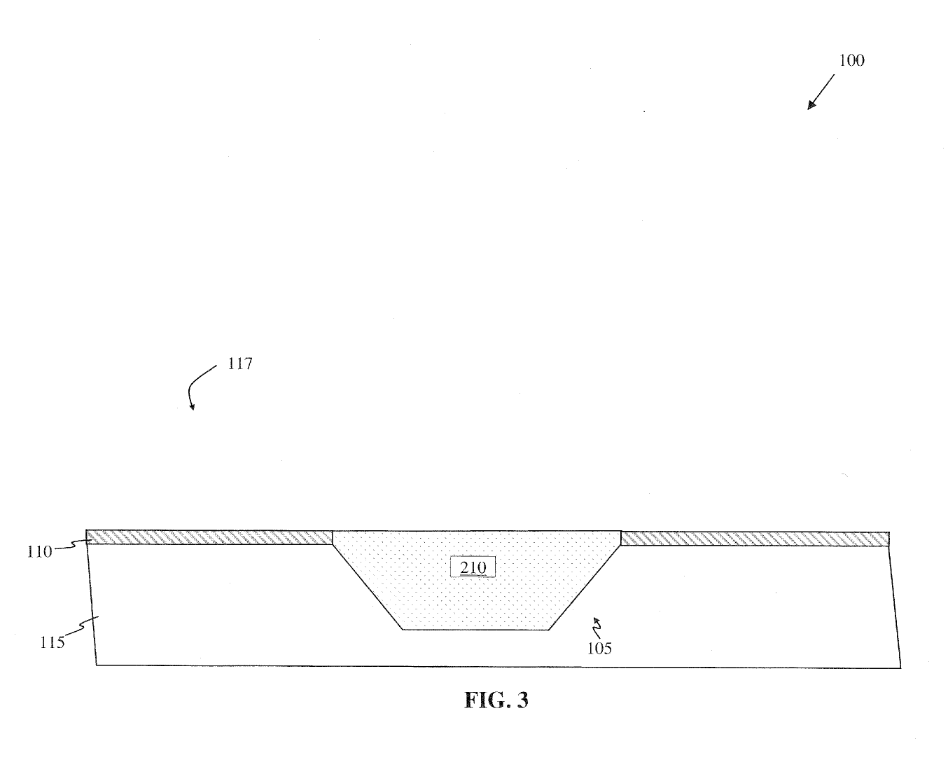

FIG. 3 shows the device 100 after removing the thick insulating layer 230 (FIG. 2) from outside of the trench opening 140 and after removing the patterned nitride layer 120 (FIG. 2) from the substrate 115. E.g., the thick insulating layer 230 can be removed by conventional chemical mechanical polishing (CMP), using the nitride layer 120 as a CMP stop layer. The nitride layer 120 can then be removed using a nitride wet etch process (e.g., hot phosphoric acid). E.g., in some embodiments, the nitride layer 120 is exposed to about 85 to 92 wt percent H₃PO₄ at about 155 to 180° C. for about 20 to 45 minutes. As illustrated in FIG. 3, the pad oxide layer 110 and STI insulator 210 are substantially unaffected by the wet etch process used to remove the nitride layer 120.

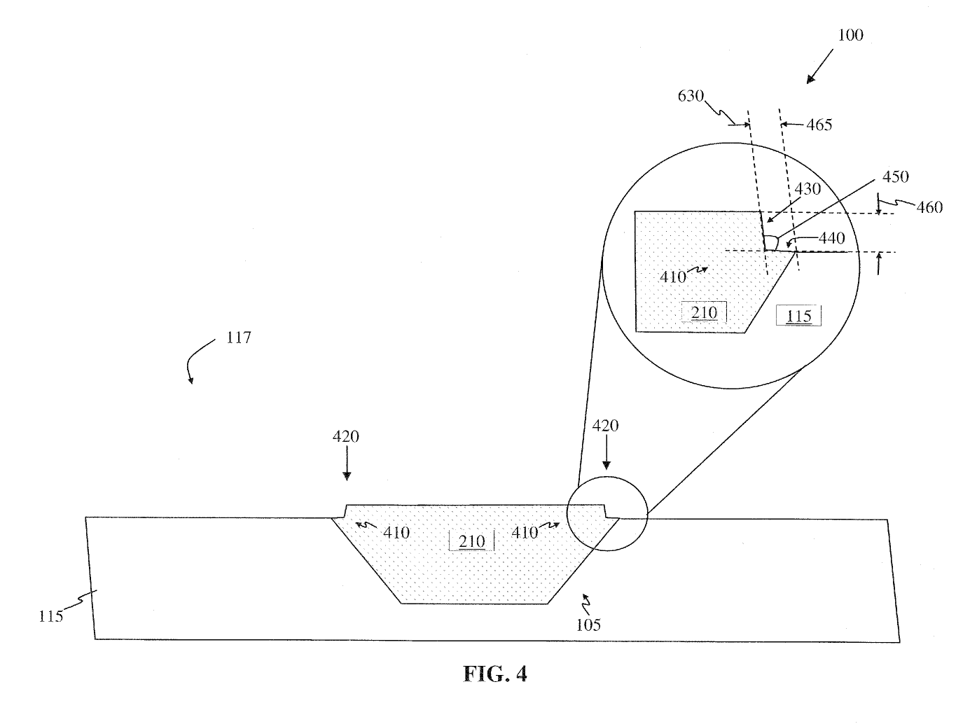

FIG. 4 shows the device after removing the patterned pad oxide layer 110 (FIG. 3) using a wet etch process. Embodiments of the wet etch process can include an aqueous solution of hydrofluoric acid to strip the pad oxide layer 110 (FIG. 3) from the substrate 115. E.g., in some cases, the wet etch process includes exposing the patterned pad oxide layer 110 to about 0.5 wt hydrofluoric acid in water for a duration of about 4 to 6 minutes and temperature ranging from about 23 to 26° C.

As also shown in FIG. 4, a consequence of the wet etch process is that a divot 410 is formed on upper lateral edges 420 of the trench insulator 210. The term divot 410 as used herein refers to an opening in the upper edges 420 the insulator 210 having a vertical wall 430 and lateral base 440 (shown in expanded view in FIG. 4). The lateral base 440 is substantially coplanar with the substrate surface 117 (e.g., within about 10 degrees). The vertical wall 430 is the surface of the insulator 210 that is uncovered after removing the pad oxide layer 420. The vertical wall 430 forms an angle 450 with the lateral base 440 that ranges from about 60 to 120 degrees, and to increase the selectivity of the dry etch discussed below, more preferably about 90 degrees.

The divot 410 is configured to have dimensions large enough to facilitate the formation of the nitride posts, as further discussed below. In some embodiments, e.g., the vertical wall 430 has a step height 460 (e.g. distance from the lateral base 440 to the substrate surface 117) of at least about 5 nm, and the lateral base 440 a width 465 (e.g., distance from the vertical wall 430 to the lateral edge 420) of at least about 2.5 nm.

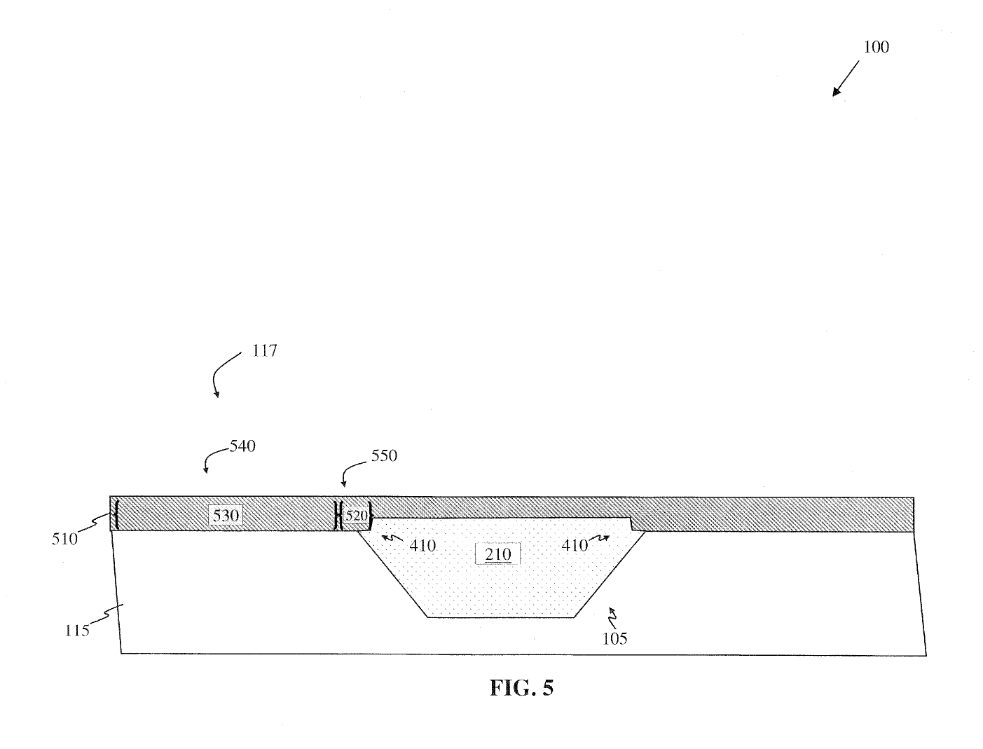

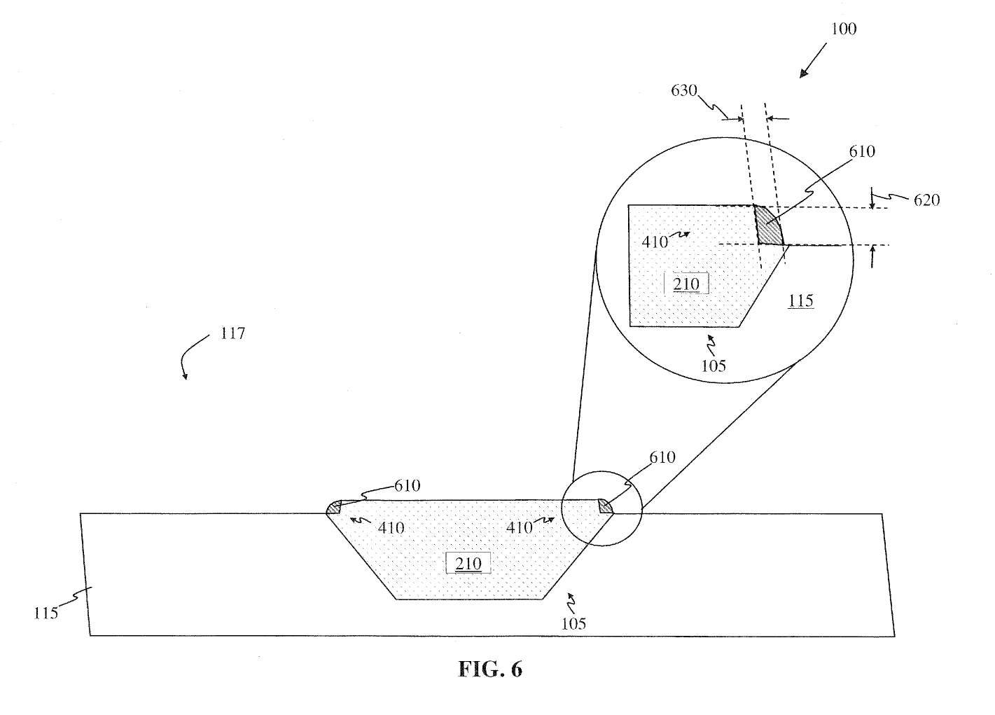

FIGS. 5 and 6 show the device 100 at different stages of forming a nitride post of the STI structure 105. FIG. 5 shows the device 100 after depositing a nitride layer 510 (e.g., silicon nitride, or silicon oxynitride layer) on the insulator 210, including filling the divot 410. As shown in FIG. 5, the nitride layer 510 may be blanket deposited over (e.g., fully cover) the entire substrate 115. In some cases, depositing the nitride layer 510 includes a plasma enhanced CVD (PECVD) process. E.g., the PECVD process can includes a gas flow of ammonium (NH₃) and silane (SiH₄, or more generally SiₙH₂ₙ₊₂) having a sccm ratio ranging from about 40:60 to 60:40, plasma power of about 500 W and pressure of about 100 mTorr. In some cases, the sccm ratio of NH₃ and silane equals about 50:50. Substantially lower amounts of silane may impede the removal of nitride, while substantially higher amounts of ammonium may deleteriously increase the removal of nitride. FIG. 5 shows the nitride layer 510 having a portion 520 that is adjacent (e.g., within about 100 nm) of the divot's vertical wall 430 (FIG. 4) and a second portion 530 that is remote from the wall 430.

With continuing reference to FIGS. 4-5, FIG. 6 shows the device after dry etching the nitride layer 510 to thereby form a nitride post 610 on the vertical wall 430 of each of the divots 410. The dry etch process is selective towards the nitride layer located adjacent to the vertical wall 430 such that the portion 520 of the nitride layer 510 remains on the vertical wall 430 subsequent to the dry etching, thereby being converted into the post 610. E.g., in some cases, the dry etch removes a horizontal surface 540 of the remote portion of the nitride layer 530 (e.g., greater than about 50 nm from the vertical wall 430) about 100 times faster than from a surface 550 of the portion of nitride layer 520 that is located adjacent to the vertical wall 430 (e.g., within about 50 nm of the vertical wall 430 shown in FIG. 4).

In some cases, the dry etch process includes a fluorocarbon gas and inert gas mixture having a sccm ratio ranging from about 20:60 to 40:40. E.g., dry etching can comprise a mixture of fluorocarbon gas of CF₄ and inert gas of argon, in a sccm ratio ranging from about 25:50. In some cases, dry etching includes a substrate 115 temperature of about 30° C., a pressure of about 10 mTorr, and a RF-power of about 700 Watts. In some embodiments, of the STI structure 105, each of the nitride posts 610, has a height 640 ranging from about 2.5 nm to 10 nm and a width 650 ranging from about 2.5 nm to 10 nm.

In some cases, the height 620 of the nitride post 610 is substantially equal (e.g., within about 10 percent) to the step height 460 of the vertical wall 430 of the divot 410. In some case both the height 620 and a width 630 of the nitride post 610 are substantially equal to the step height 460 and width 465 of the lateral base 440. E.g., when the divot 410 has a step height 460 of about 5 nm and a width 465 of about 2.5 nm, the post's 610 height 620 and width 630 equal about 5.0±0.5 nm and 2.5±0.25 nm, respectively.

After forming the STI structure 105, the method of manufacturing the semiconductor device 100 can include numerous additional fabrication steps to complete the device 100. Some of these steps could potentially expand the size of the divot 410, with consequent detrimental effects on the device's 100 manufacture. The presence of the nitride post 610 mitigates these effects by deterring the divot's 410 expansion.

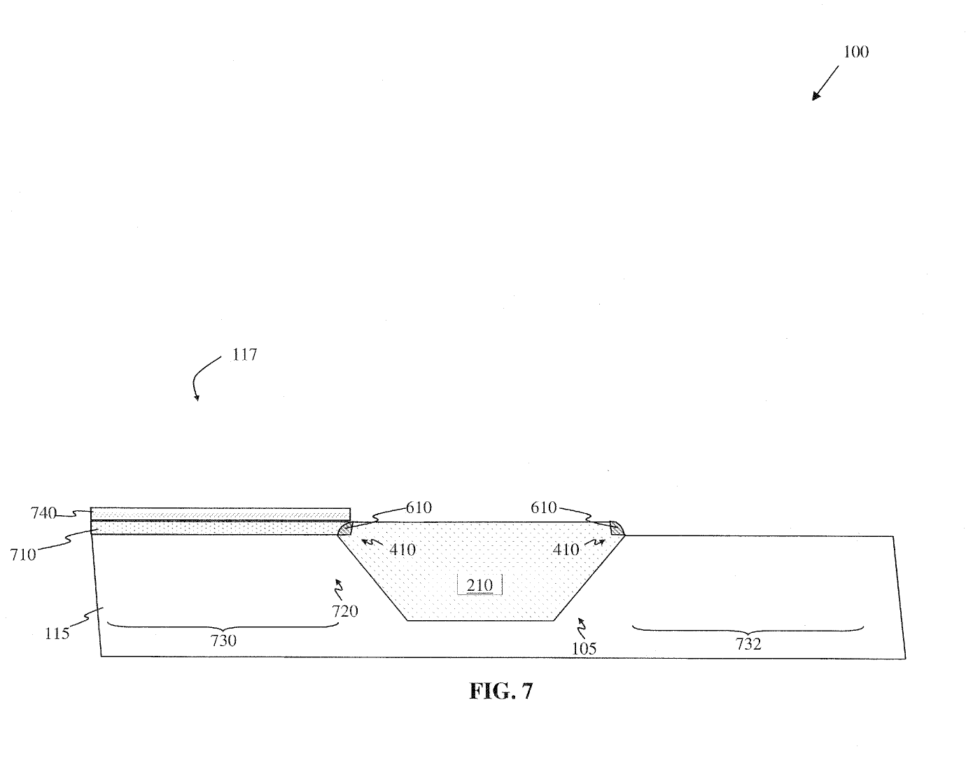

E.g., FIG. 7 shows the device 100 after a forming a gate oxide layer 710 on the substrate 115 and adjacent to the nitride post 610. E.g., a thick (about 500 nm) gate oxide layer 710 can be deposited over the substrate 115 using a TEOS CVD process or other conventional oxide deposition processes. The gate oxide layer 710 can be formed as part of the manufacture of an active device 720, such as a transistor used in high voltage application. E.g., the gate oxide layer 710 can be a high voltage gate oxide for one or more transistors used in high voltage applications. The active device 720 is located on or in one of the active areas 730 of the substrate 115, and is adjacent to the STI structure 105, or between STI structures 105.

FIG. 7 also shows the device 100 after locally removing the gate oxide layer 710. For other the active areas 732, a second wet etch process can be used to locally remove a portion of the gate oxide layer 710, e.g., to allow a thinner gate oxide (e.g., a low voltage gate oxide layer, not shown) to be formed in this location. Portions of the gate oxide layer 710, configured for use as a high voltage gate oxide, can be covered with a photoresist layer 740 to protect against the removal of the gate oxide layer 710 in active area 730 of FIG. 7 during the second wet etch. In some embodiments, the second wet etch process comprise exposing the unmasked portions of the gate oxide layer 710 (e.g., in active area 732 of FIG. 7) to about 0.5 to 1 weight percent hydrofluoric acid in about 40 wt % ammonium fluoride and balance distilled water at about 23 to 26° C. for about 20 to 180 seconds. In the absence of having nitride posts in the STI structure, the second wet etch could substantially expand (e.g., at least double) the size of the divot 410.

The presence of the nitride posts 610, however, helps to prevent the second wet etch process from further increasing the size of the divot. For instance, in some embodiments, the step height 460 of the vertical wall 430 and the width 465 of the lateral base 440 are changed by about 10 percent or less, as compared to the height 460 and width 465 prior to the second wet etch (FIG. 4). Consequently, the various problems associated with having larger divots in the STI structure 105 during latter fabrication steps, or problems with the functionality of the final manufactured device 100, are thereby reduced.

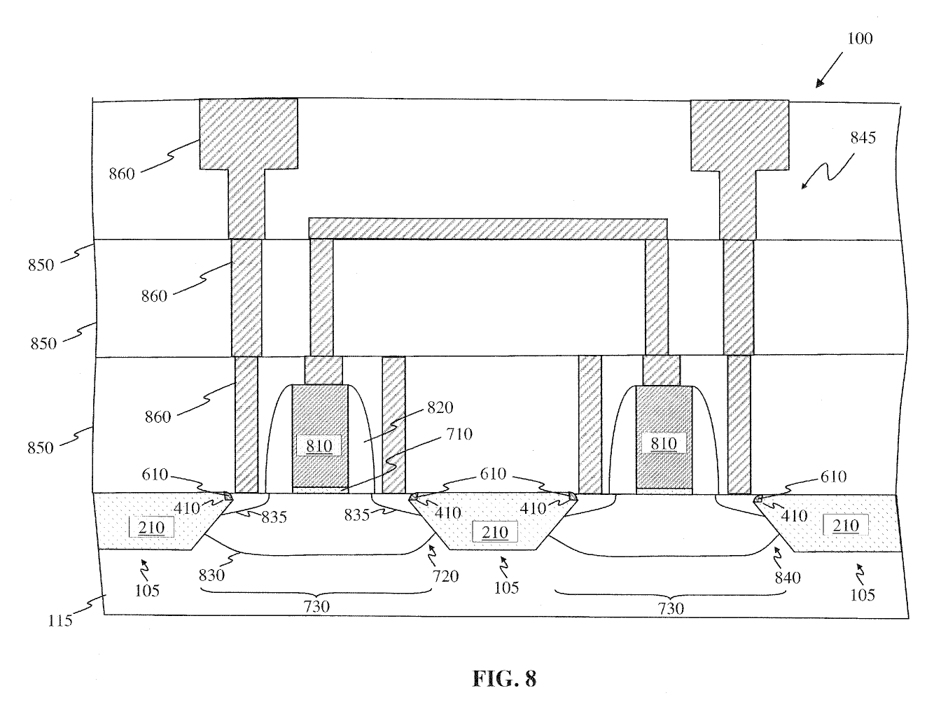

FIG. 8 shows a lower magnification view of the semiconductor device 100 after performing additional conventional fabrication steps to complete the device's 100 manufacture. E.g., as part of forming the active device 720, after reducing the thickness of the gate oxide layer 710, a gate electrode 810 (polysilicon, metal, or combinations thereof) can be formed on the gate oxide layer 710, and gate sidewalls 820 formed on sides of the gate electrode 810. The substrate 115 can be doped with n- or p-type dopants to form a doped well 830 and source and drain regions 835 of the active device 720.

The active device 720, when configured as a transistor, can be an nMOS transistor a pMOS transistor or combination thereof (e.g., CMOS device). The active device 720 configured as a transistor can be coupled to other active devices 840 (e.g., transistors) to form an integrated circuit 845. Insulating layers 850 (e.g., pre-metal and interlayer dielectric layers) can be formed on the substrate 115, and interconnects 860 (e.g., copper, tungsten or aluminum-containing lines or contacts) formed within the insulating layers 850 to interconnect the active devices 720, 840.

FIG. 8 also illustrates another embodiment of the disclosure, a semiconductor device 100. Embodiments of the device 100 include a STI structure 105. The STI structure 105 includes a silicon oxide insulator 210 filling a trench 160 in a semiconductor substrate 115. Upper edges 420 of the silicon oxide insulator 210 each have a divot 410, the divot 410 having at least one vertical wall 430. The device 100 also comprises a silicon nitride post 610 on the vertical wall 430 (FIG. 4). A height 620 of the silicon nitride post 610 is substantially equal to (e.g., within 10 percent of) a step height 460 (FIG. 4) of the divot 410. The device 100 also comprises a transistor 720 adjacent to the STI structure 205.

Those skilled in the art to which the disclosure relates will appreciate that other and further additions, deletions, substitutions, and modifications may be made to the described example embodiments, without departing from the disclosure.

What is claimed is:

1. A method of manufacturing a semiconductor device, comprising:
forming a shallow trench isolation structure, including:
performing a wet etch process to remove a patterned pad oxide layer located on a semiconductor substrate, thereby producing a divot on upper lateral edges of a insulator-filled trench in said semiconductor substrate; and
forming a nitride post on a vertical wall of said divot, including:
depositing a nitride layer on said insulator; and
dry etching said nitride layer, wherein said dry etch is selective towards said nitride located adjacent said vertical wall such that a portion of said nitride layer remains on said vertical wall subsequent to said dry etching.

2. The method of claim 1, wherein said wet etch process includes an aqueous solution of hydrofluoric acid.

3. The method of claim 1, wherein said wet etch process includes exposing said patterned pad oxide layer to about 0.5 weight percent hydrofluoric acid in water for a duration of about 4 to 6 minutes and temperature ranging from about 23 to 26° C.

4. The method of claim 1, wherein depositing said nitride layer includes a plasma enhanced chemical vapor deposition process.

5. The method of claim 4, wherein said plasma enhanced chemical vapor deposition process includes a gas flow of NH3 and silane having a sccm ratio ranging from about 40:60 to 60:40, plasma power of about 500 W and pressure of about 100 mTorr.

6. The method of claim 5, wherein said sccm ratio of NH₃ and silane equals 50:50.

7. The method of claim 4, wherein said plasma enhanced chemical vapor deposition process includes a plasma power of about 500 W and pressure of about 100 mTorr.

8. The method of claim 1, wherein said dry etching includes a fluorocarbon gas and inert gas mixture having a sccm ratio ranging from about 20:60 to 40:40.

9. The method of claim 1, wherein said dry etching includes a fluorocarbon gas of CF₄ and inert gas of argon mixture having a sccm ratio ranging from about 25:50.

10. The method of claim 1, wherein said dry etching includes a substrate temperature of 30° C., a pressure of 10 mTorr, and an RF-power of about 700 W.

11. The method of claim 1, wherein said dry etching removes a horizontal surface of said nitride layer about 100 times faster than said nitride layer located adjacent said vertical wall.

12. A method of manufacturing a semiconductor device, comprising:
forming a shallow trench isolation structure, including:
depositing a pad oxide layer and a nitride layer on a semiconductor substrate;
patterning said nitride layer, said pad oxide layer, and said substrate to form a trench opening in said substrate;
filling said trench opening with an insulator;
performing a wet etch process to remove said pad oxide from said substrate, thereby producing a divot on upper lateral edges of said insulator; and
forming a nitride post on a vertical wall of said divot, including:
depositing a nitride layer on said insulator; and
dry etching said nitride layer, wherein said dry etch is selective towards said nitride located adjacent said vertical wall such that a portion of said nitride layer remains on said vertical wall subsequent to said dry etching;
forming a gate oxide layer on said substrate, adjacent to said nitride post; and
masking portions of said gate oxide layer, and locally removing unmasked portions of said gate oxide layer using a second wet etch process.

13. The method of claim 12, wherein said nitride post prevents said second wet etch process from further increasing a size of said divot.

14. The method of claim 12, depositing said nitride layer includes a plasma enhanced chemical vapor deposition process includes a gas flow of NH₃ and silane having a sccm ratio of about 50:50, a plasma power of about 500 W and pressure of about 100 mTorr.

15. The method of claim 12, wherein said dry etching includes a fluorocarbon gas and inert gas mixture having a sccm ratio of about 25:50, a substrate temperature of 30° C., a pressure of 10 mTorr, and a radio frequency-power of about 700 W.

16. A semiconductor device, comprising:
a shallow trench isolation structure, including:
a silicon oxide insulator filling a trench in a semiconductor substrate, wherein upper edges of said silicon oxide insulator each have a divot, said divot having at least one vertical wall;
a silicon nitride post on said vertical wall, wherein a height of said silicon nitride post is substantially equal to a step height of said divot; and
a transistor adjacent to said shallow trench isolation structure.

17. The circuit of claim 16, wherein said height said silicon nitride post ranges from about 2.5 nm to 10 nm and a width of said silicon nitride post ranges from about 2.5 nm to 10 nm.

18. The circuit of claim 16, wherein said transistor is a pMOS or nMOS transistor and is located between two of said shallow trench isolation structures.

19. The circuit of claim 16, where said transistor is coupled to other transistors to form an integrated circuit.
